(19) United States
(12) Patent Application Publication
(10) Pub. No.: US 2017/0361626 A1
(43) Pub. Date: Dec. 21, 2017

(54) COATING DEVICE

(71) Applicant: Hewlett-Packard Development Company, L.P., Houston, TX (US)

(72) Inventors: Lokendra Pal, San Diego, CA (US); Xulong Fu, San Diego, CA (US); Alan Jacques, San Diego, CA (US)

(21) Appl. No.: 15/540,373

(22) PCT Filed: Jan. 28, 2015
(86) PCT No.: PCT/US2015/013210

§ 371 Date: Jun. 28, 2017

(51) Int. Cl. B41J 11/00; C23C 16/02

(52) U.S. Cl. CPC B41J 11/0015; C23C 16/0209

(57) ABSTRACT

The present disclosure is drawn to a coating device and a method of manufacturing a coated media substrate. The coating device can comprise a pre-moisturizer and pre-heater unit to apply heat and moisture to a media substrate; a coating composition applicator to apply a wet coating composition to the media substrate after it has been heated and moisturized by the pre-moisturizer and pre-heater unit; and a dryer to receive the media substrate having the wet coating composition applied thereto and to remove moisture, thereby generating a coated media substrate.

### BACKGROUND

There are several reasons that inkjet printing has become a popular way of recording images on various media surfaces, particularly paper. Some of these reasons include low printer noise, variable content recording, capability of high speed recording, and multi-color recording. Inkjet printing continues to improve; however, accompanying these improvements are increased demands by consumers in this area, e.g., higher speeds, higher resolution, full color image formation, increased stability, etc. Achieving or maintaining a high optical density, as well as, retaining reduced print bleed can be challenging. Coated media typically used for this type of printing can often perform acceptably on these types of inkjet printing devices. However, there is still room for improvement as it relates to the process of coating media substrates.

### BRIEF DESCRIPTION OF THE DRAWINGS

FIG. 1 is a cross-sectional view of the coating device including a pre-moisturizer and pre-heating unit, coating composition applicator, and a dryer in accordance with examples of the present disclosure; and

FIG. 2 is a cross-sectional view of the coating device including a pre-moisturizer and pre-heating unit, coating composition applicator, dryer, and air to air heat exchanger in accordance with examples of the present disclosure; and

FIG. 3 is a cross-sectional view of the coating device including a pre- moisturizer and pre-heating unit, coating composition applicator, dryer, and cooler in accordance with examples of the present disclosure; and

FIG. 4 is a cross-sectional view of the coating device including a pre-moisturizer and pre-heating unit, coating composition applicator, dryer, air to air heat exchanger, and cooler in accordance with examples of the present disclosure; and

FIG. 5 is a cross-sectional view of the coating device including a pre-moisturizer and pre-heating unit, coating composition applicator, and dryer that is attached to a web press printer, wherein the heated moist air from the printer dryer is circulated into the coating device in accordance with examples of the present disclosure;

FIG. 6 is a cross-sectional view of the coating device including a pre-moisturizer and pre-heating unit, coating composition applicator, and dryer that is attached to a web press printer and an overprint varnish device, wherein the heated moist air from a printer dryer and a overprint varnish dryer is circulated into the coating device in accordance with examples of the present disclosure; and

FIG. 7 is a cross-sectional view of the coating device including a pre-moisturizer and pre-heating unit, coating composition applicator, and dryer that is attached to a web press printer and an overprint varnish device, wherein the heated moist air from a printer dryer and a overprint varnish dryer is circulated into the coating device in accordance with the examples of the present disclosure.

### DETAILED DESCRIPTION

Before the present disclosure is described, it is to be understood that this disclosure is not limited to the particular process steps and materials disclosed herein because such process steps and materials may vary. It is also to be understood that the terminology used herein is used for the purpose of describing particular examples only. The terms are not intended to be limiting because the scope of the present disclosure is intended to be limited only by the appended claims and equivalents thereof.

Obtaining high print quality from certain inks on uncoated paper can be challenging because of issues such as bleed, feathering, colorant migration, or the like. In accordance with the present disclosure, coatings can be applied to various media substrates, including paper, that provide acceptable image quality and in some instances, improvement in optical density. The device described in the present disclosure can prevent certain problems that many coating systems encounter. First, it can be hard to achieve uniform coating on all types of paper, especially on rough papers. Second, following coating, the paper can cockle or curl as it dries. These issues raise quality control concerns with inkjet printing on coated media.

The present disclosure is drawn to a coating device that is designed to provide uniform surface coating, either on one side or on both sides of a media substrate, while preventing cockling, curling, or the like. For example, a coating device can include a pre-moisturizer and pre-heater unit to apply heat and moisture to a media substrate. The device can also include a coating composition applicator to apply a wet coating composition to the media substrate after it has been heated and moisturized by the pre-moisturizer and pre-heater unit. A dryer can also be present to receive the media substrate having the wet coating composition applied thereto and to remove moisture, thereby generating a coated media substrate. In various examples, an air flow director can be present to direct moistened and heated air from the dryer (or other driers down line) back to the pre-moisturizer and pre-heater unit.

In another example, a method of preparing a coated media substrate can include feeding a media substrate into a coating device, wherein the coating device includes a pre-moisturizer and pre-heater unit, a coating composition applicator, and a dryer. Additional steps include applying moisture and heat to the media substrate within the pre-moisturizer and pre-heater unit at a relative humidity from about 50% to about 100% and a temperature from about 40° C. and 200° C. to generate a pre-moistened and pre-heated media substrate, and applying a coating composition to the pre-heated and pre-moistened media substrate with the coating composition applicator to generate a coated wet media substrate. This is followed by drying the coated media substrate to generate the coated media substrate. In one example, this method can include directing moistened and heated air from the dryer (or any drier in the device) back to the pre-moisturizer and pre-heater unit.

Various arrangements can include various sub-units. For example, in device, there can be a pre-moisturizer and pre-heater unit, a coating composition applicator, and a dryer. In another device, a pre-moisturizer and pre-heater unit, a coating composition applicator, a dryer, and an air to air heat exchanger can be present. In yet another aspect, the device includes a pre-moisturizer and pre-heater unit, a coating composition applicator, a dryer, an air to air heat exchanger, and a cooler. In a further aspect, the device includes a pre-moisturizer and pre-heater unit, a coating composition applicator, a dryer, and a cooler.

As shown in FIG. 1, the device can include a pre-moisturizer and pre-heater unit 1, a coating composition applicator 4, and a dryer 5. A media substrate 2 (shown schematically using an arrow defining a pathway) is loaded into the coating device where it is initially moisturized and heated by the pre-moisturizer and pre-heater unit. The pre-moisturizer and pre-heater unit has controls 3, that allow a user or computer to adjust the amount of moist heat that is applied to one or both sides of the surface of the media substrate. The media substrate is then coated by the coating composition applicator and dried in the dryer. In this aspect, air 6 (which is moisturized or humidified from the moisture that comes off in the dryer) is circulated from the dryer to the pre-moisturizer and pre-heater unit. The hot moist air that is circulated from dryer is used to heat and moisturize the media substrate in the pre-moisturizer and pre-heater unit. Because the air is constantly being recirculated and less ambient air enters the system, the device can run with reduced energy costs than what would otherwise be present.

As a note, it is understood that various air flow schemes are shown in each of FIGS., e.g., the air flow shown at 6 in FIGS. 1-7. In order to achieve these air flows, it is likewise understood that various air flow directing devices can be used to generate and channel air flow. Though these “air flow directors” are not specifically shown, it is understood that air flow directors can include, for example, pipes, ducting, air blowers, pressure devices, or the like, to generate and direct air flow. The media substrate, coated media, dried coated media, etc., can be carried from one device to the next using a conveyer system, e.g., conveyor belt, roll-to-roll media, etc. These specific variations are not shown, but are shown schematically coincident with media substrate 2.

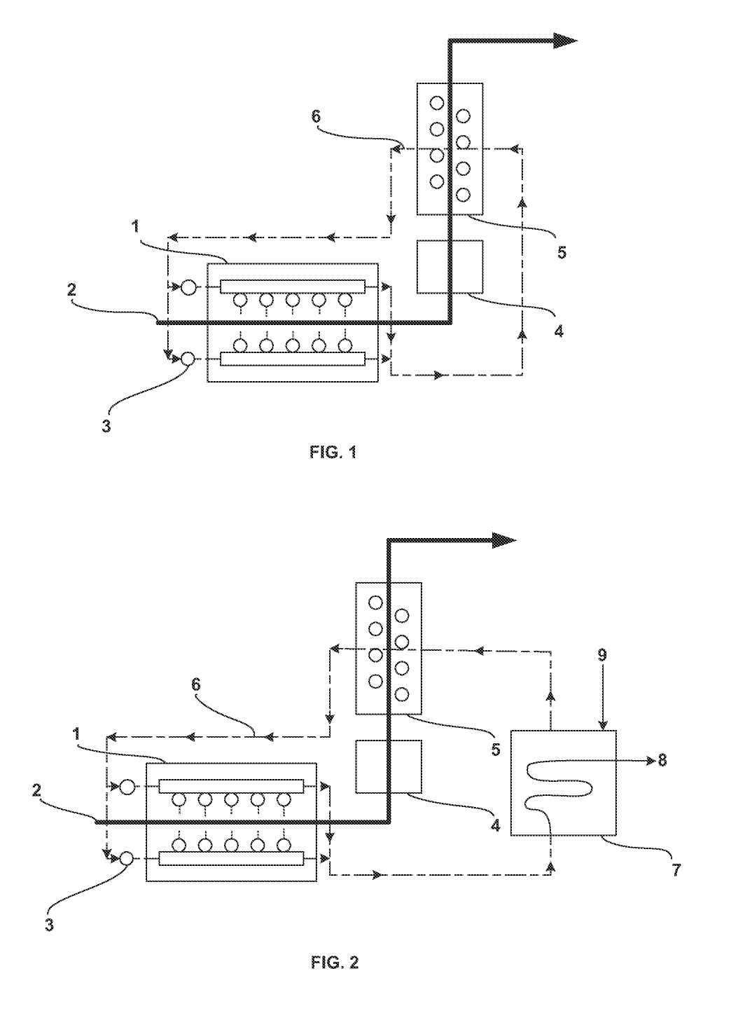

Turning now to FIG. 2, a similar device to that shown in FIG. 1 is provided, except that the device further includes an air to air heat exchanger 7. In this example, the air to air heat exchanger recovers the remaining heat by providing some ambient air to the system that comes in contact with the pre-moisturized and pre-heated air. In this aspect, a media substrate 2 is loaded into the coating device where it is initially moisturized and heated by the pre-moisturizer and pre-heater unit 1. The pre-moisturizer and pre-heater unit has controls 3 that allow a user or computer to adjust the amount of moist heat that is applied to one or both sides of the media substrate. The media substrate is then coated by the coating composition applicator 4 and dried in the dryer 5. In this aspect, air 6 is circulated from the dryer to the pre-moisturizer and pre-heater unit, thus providing heat and moisture to the pre-moisturizer and pre-heater unit through a recirculation process. The air to air heat exchanger, where a portion of the air exits 8 the system, is also present. Essentially, ambient air 9 enters the system at the air to air heat exchanger and mixes with air from the pre-moisturizer and pre-heater unit (prior to entering the dryer). Furthermore, the air to air heat exchanger allows for a portion of the air from the pre-moisturizer and pre-heater unit to exit the system and for fresh ambient air to enter the system where it passes through the dryer. In the dryer, the air becomes heated and moisturized (again after a cycle) as water and other volatiles evaporate off the coating on the media. The air then circulates to the pre-moisturizer and pre-heater unit.

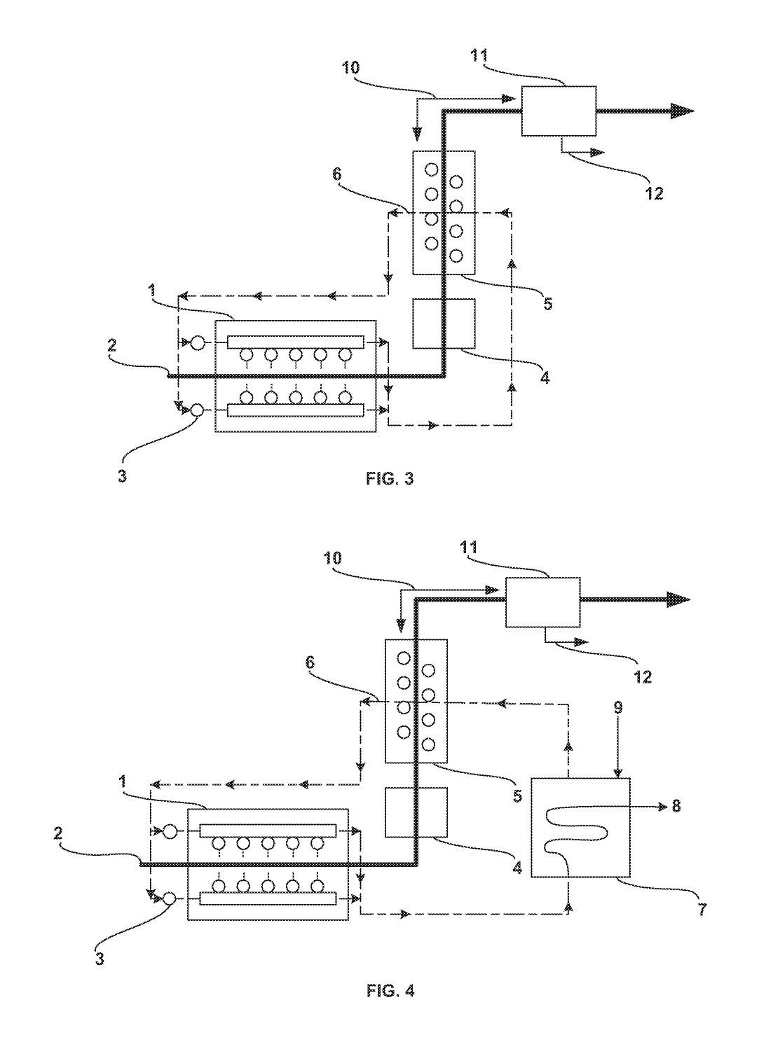

As shown in FIGS. 3 and 4, again, these devices include a pre-moisturizer and pre-heater unit 1, a coating composition applicator 4, and a dryer 5, as well as, controls 3 as described above. In either of the two devices (FIGS. 3 and 4), a cooler 11 can be included. When a cooler is present, the system can be designed to circulate ambient air 10 into the cooler and/or the dryer. After the media substrate 2 is cooled, the ambient air in the cooler exits the cooler (at 12). The use of a cooler in the system prevents the interaction of the hot coated media with the roller and decreases the chance of the coated media becoming physically deformed as it exits the coating device. As can be seen, FIG. 4 further includes an air to air heat exchanger 7, similar to that described with respect to

FIG. 2. Air 6,8,9 flows similar to those described in FIGS. 1 and 2.

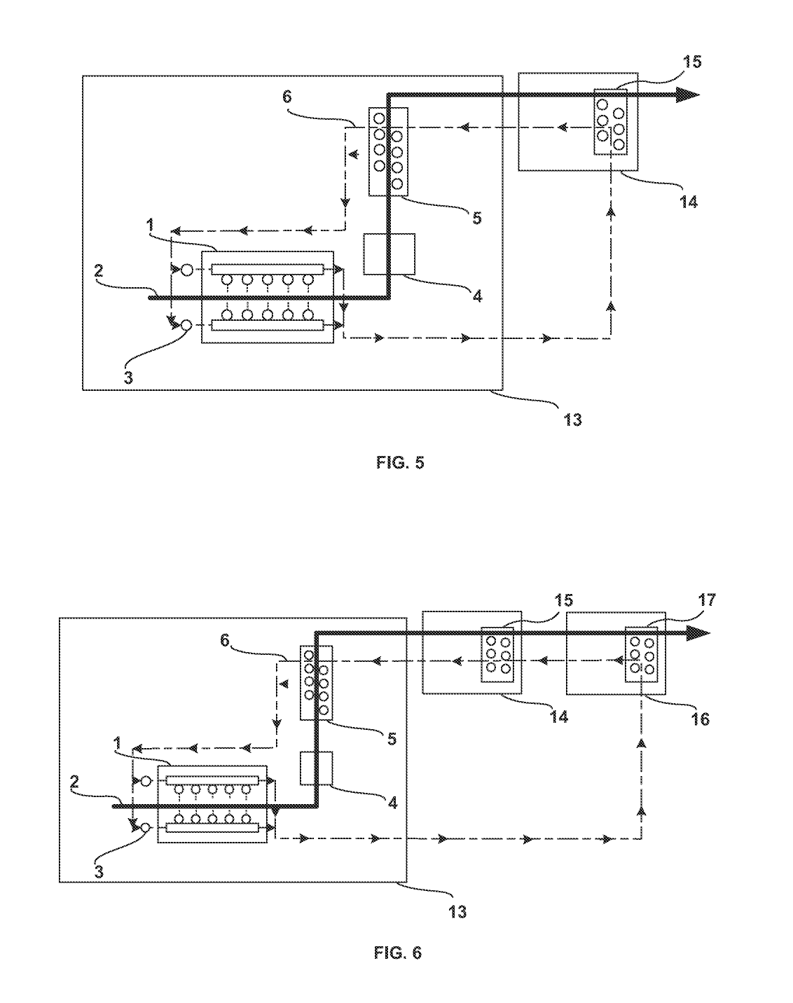

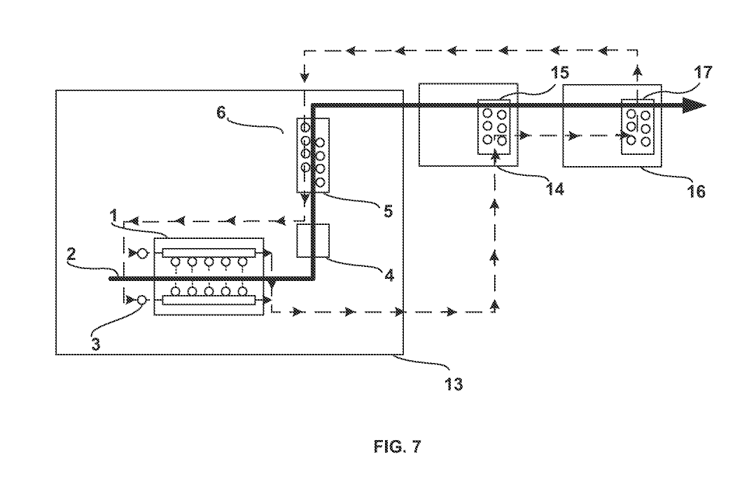

In further aspects shown generally in FIGS. 5-7, any of the coating devices discussed above can be coupled to other devices in either an inline or offline system. In one aspect, as shown in FIG. 5, the coating device can be coupled to a web press printer 14, such as HP T200 series, T300 series, or T400 series Color Inkjet Web Presses. Alternatively, as shown in FIG. 6 and FIG. 7, a web press printer and an overprint varnisher 16, such as an inline overprinting varnishing device. When the coating device is coupled to either of these devices, air 6 can be circulated between the internal dryer in the coating unit 5, as well as from any other dryer (e.g., dryer 15 in the web press and/or dryer 17 in the overprint varnish device) that is in line with the system, and the pre-moisturizer and pre-heater unit 1. For example, as shown in FIG. 5, when the coating device is attached to the web press printer, the air can be circulated to the pre-moisturizer and pre-heater unit from either or both the printer dryer and the dryer in the coating device. In another example, as shown in FIG. 6, the coating device may be attached to the web press printer and the overprint varnish device. In this embodiment, air can be circulated to the pre-moisturizer and pre-heater unit from the dryers in the coating device, the dryer in the printer, and/or the dryer in the overprint varnish device in the order shown. In yet another example, as shown more specifically in FIG. 7, the coating device may be attached to the web press printer and overprint varnish device. In this embodiment, exhaust air can be circulated first from the printer, then the overprint varnish dryer, then to the coating device dryer, and then to the pre-moisturizer and pre-heater unit. Circulating the air from at least one drying unit, provides moisture to the air (and heat), and thus, can reduce the energy cost associated with using the coating device. In each of the examples, specifically FIGS. 5, 6, and 7, the other structures shown, including the media substrate 2, controls 3, the coating composition applicator 4, and the like are as described in the prior figure descriptions. It is also noted that a cooler (not shown) and/or an air to air heat exchanger (not shown) can likewise be used in these examples.

In the coating devices disclosed herein, the pre-moisturizer and pre-heater unit is used to both heat and moisturize the media substrate. This (both heat and moisture) allows for uniform surface coating and better dimensional stability such as flatness and curl or cockle control, which ultimately results in better processing through the printing and finishing device and print quality on the coated media. Thus, in some examples, the present device specifically can allow for improved coating transfer and uniformity to the substrate, improved curl balance by controlling moisture up-take on each side of the media substrate, and/or reduced energy costs associated with running the device. Additionally, the coating devices herein can be coupled to web press printers and/or overprint varnish devices allowing for the media substrate to be pre-conditioned, primed, and printed within a short a matter of time.

In further detail, the pre-moisturizer and pre-heater unit can be designed to operate at a variety of temperatures. In one aspect, the pre-moisturizer and pre-heater unit can be configured to operate at a temperature from about 40′C to about 200′C. In another aspect, the pre-moisturizer and pre-heater unit can be configured to operate at a temperature from about 65° C. to about 200° C. In yet another aspect, the pre-moisturizer and pre-heater unit can be configured to operate at a temperature range from about 50° C. to about 100° C.

The pre-moisturizer and pre-heater unit can also designed to operate at a variety of humidity ranges. In one aspect, the pre-moisturizer and pre-heater unit can be configured to operate at a humidity range from about 50% to about 100%. In another aspect, the pre-moisturizer and pre-heater unit can be configured to operate at a humidity range from about 60% to about 100%. In yet another aspect, the pre-moisturizer and pre-heater unit can be configured to operate from about at a humidity range from about 55% to about 95%.

The pre-moisturizer and pre-heater unit can be used to moisturize and heat one or both sides of the media substrate. In one aspect, the pre-moisturizer and pre-heater unit can be configured with separate controls that allow a user or computer to adjust the amount of moist heat (e.g., heat and humidity can be controlled independently) that is applied to the front side of the media substrate, as well as the amount of moist heat that is applied to the back side of the media substrate. These heat and/or moisture levels can be independent on each side of the media substrate, or can be set to be the same on each side of the media substrate.

In another aspect, a user or computer can adjust the level of moisture applied to media substrate based on the thickness and texture of the media substrate. The ability to adjust the level of moisture applied to the media substrate is beneficial because the thicknesses and texture of the media impacts the media substrates receptiveness to coating. Applying the coating to a moist, heated media improves fixing of the coating composition to the media. Moist heat can smooth the surface of the media which allows for a uniform application and uptake of the coating regardless of the surface texture. A moist, heated media substrate can be more pliable and more receptive to the coating than the same media substrate that is dry and at room temperature.

A coating composition applicator can be used to apply the coating composition (after heat and humidification) to the media. The coating composition applicator can coat the media using any method known in the art. For example, the coating composition applicator can apply the coating by spray coating, dip coating, cascade coating, roll coating, gravure coating, flexo coating, anilox roller coating, curtain coating, air knife coating, cast coating, Mayer rod coating, blade coating, film coating, metered size press coating, puddle size press coating, calender stack, and/or by using other known coating techniques. In one example, the coating composition applicator applies the coating using knife coating, anilox roller coating, blade coating, or curtain coating.

The thickness selected for each coat layer can depend upon the particular desired property or application, and can be applied to one or both sides of the media substrate. In one aspect, the coating can be applied to one or both sides of the media substrate at an independent basis weight of about 0.2 gsm to about 10 gsm. In another aspect, the coating can be applied to one or both sides of the media substrate at an independent basis weight of about 0.3 gsm to about 10 gsm. In another aspect, the coating can be applied to either or both sides of the media substrate at an independent basis weight of about 0.5 gsm to about 3 gsm. In either case, whether simplex or duplex coating, a user or computer can balance the amount of moisture applied with the amount of coating applied to the media substrate to prevent or reduce curling and/or cockling.

Any coating that is suitable for use on the media substrate, as well as, any other additives that can be used in conjunction with the coating to enhance the properties of substrate and allow for better printing, can be applied by the coating composition applicator. In one aspect, the coating composition can include from about 20 wt % to about 90 wt % solids, and from about 10 wt % to about 80 wt % fluids. In another aspect, the coating composition can include about 35 wt % to about 45 wt % of solids and from about 60 wt % to about 65 wt % fluid. The fluid component in the coating evaporates from the coating composition and provides some or all of the moisture to the air in the dryer, and the solids remain behind as a coating layer on the media substrate. Fluid components can be water, solvent, and/or the like. Solids can include polymer, salt, inorganic pigment, organic pigment, optical brightener, sizing agents, slip control agents, and/or the like.

After the coating is applied, the coated medium is dried in a dryer. The dryer can be any oven type dryer such as an air convection, infrared radiation, or a hybrid dryer, for example. Regardless of the type of dryer, the dryer in the device can allow for air to be circulated from the dryer back to the pre-moisturizer and pre-heater unit.

The coating devices described above, can be suitable for use on any type of substrate of print media. Suitable examples include, but are not limited to include, cellulose based paper, fiber based paper, other paper media, nonporous media, swellable media, microporous media, photobase media, offset media, packaging media, coated media, uncoated media, and other types of media. Other types of media can include plastics, vinyl, fabrics, and woven substrate. As a point of clarification, it is noted that certain coatings (or pre-coatings) described herein may already be present as part of a substrates, and these coatings are not the same as coatings primarily discussed in the context of the present disclosure. Offset media or photobase, for example, already include coatings on one or both side of a substrate material (and thus are considered to be part of the “substrate”). The coatings of the present disclosure, conversely, are those which are overcoated with respect to the pre-applied coatings, or alternatively, to substrates that are not already pre-coated. Such coatings, i.e. the pre-coating and/or the coating formulation of the present disclosure, can be present on either one side of a media substrate or both.

It is noted that, as used in this specification and the appended claims, the singular forms “a,” “an,” and “the” include plural referents unless the content clearly dictates otherwise.

“Substrate,” “media,” “medium,” or “media substrate” includes any base material that can be coated in accordance with the present disclosure. Further, pre-coated and film coated substrates can be considered a “substrate” that can be further coated in accordance with the present disclosure.

The root terms “humidity” and “moisture” can be used interchangeably and refer to the water content in the air with the systems and devices of the present disclosure.

The terms “circulated” and “recirclulated” are used interchangeably and both indicate flow of air from any of the heating devices described herein back to the pre-moisturizer and pre-heater device.

As used herein, the term “about” is used to provide flexibility to a numerical range endpoint by providing that a given value may be “a little above” or “a little below” the endpoint. The degree of flexibility of this term can be dictated by the particular variable and would be within the knowledge of those skilled in the art to determine based on experience and the associated description herein.

As used herein, a plurality of items, structural elements, compositional elements, and/or materials may be presented in a common list for convenience. However, these lists should be construed as though each member of the list is individually identified as a separate and unique member. Thus, no individual member of such list should be construed as a de facto equivalent of any other member of the same list solely based on their presentation in a common group without indications to the contrary.

Concentrations, dimensions, amounts, and other numerical data may be presented herein in a range format. It is to be understood that such range format is used merely for convenience and brevity and should be interpreted flexibly to include not only the numerical values explicitly recited as the limits of the range, but also to include all the individual numerical values or sub-ranges encompassed within that range as if each numerical value and sub-range is explicitly recited. For example, a weight ratio range of about 1 wt % to about 20 wt % should be interpreted to include not only the explicitly recited limits of about 1 wt % and about 20 wt %, but also to include individual weights such as 2 wt %, 11 wt %, 14 wt %, and sub-ranges such as 10 wt % to 20 wt %, 5 wt % to 15 wt %, etc.

### EXAMPLES

The following examples illustrate one possible use of the device described above to apply a coating composition to a medium. However, it is to be understood that the following are only exemplary or illustrative of the application of the principles of the present device and methods. Numerous modifications and alternative methods may be devised by those skilled in the art without departing from the spirit and scope of the present disclosure. The appended claims are intended to cover such modifications and arrangements. Thus, while the examples have been described above with particularity, the following provide further detail in connection with what are presently deemed to be the acceptable examples.

### Example 1

A coating solution is acquired having 44 wt % solids and 56 wt % fluids. The solution is loaded into a coating composition applicator of two different coating devices. One applicator includes a pre-moisturizer and pre-heater unit as shown in FIG. 1, and the other does not include this device. With an application setting for packaging paper for one side coating composition applicator set to apply the coating at 1.4 dry gsm to the print side of the medium, a smooth fiber based paper is loaded into each device. The media substrate coated using the traditional coating device, without the pre-moisturizer and pre-heating unit, exhibits a higher degree of curling than the identical device with the added preferential pre-moisturizing and pre-heating device. The flat coated media sheet can thus provide higher print quality and have better dimensional stability when printed using an HP Web Press Printer Additionally, for smooth coated packaging or other media that is to be coated on one side, there can be dimensional stability, i.e. less curl.

### Example 2

The same procedure described in Example 1 is followed except that the media substrate is a rougher textured cellulose based paper and the coating weight for each side is 1.2 gsm. Superior results are achieved with the device that includes the pre-moisturizer and pre-heater unit since applying the coating to a moist, heated media improves coating transfer and uniformity to the media. The media becomes more pliable and more receptive to the coating with moisture and heat than the same media substrate that is dry and at room temperature. This improves print uniformity when printed on the webpress. The same example can be conducted on rough uncoated media such as linerboard that may be coated on one side for inkjet printing. The linerboard that is treated with the pre-moisturizer and pre-heater unit can have better dimensional stability and print performance. The improvements can be due to moisture application on the back side for curl control and the moisture application on the front side that allows for a more uniform application of the coating.

### Example 3

The same procedure described in Example 1 is followed except that the media substrate is a thin book paper that is to be coated on both sides for printing. Thin book papers are generally a rougher coated or uncoated media. The device that includes the pre-moisturizer and pre-heater unit can provide an improved benefit during printing. For example, the media can be more pliable and more receptive to application of the coating following the application of moisture and heat than the same media substrate when application occurs when dry and at room temperature. This can thus improve print performance because the coating may be applied more uniformly across the surface of the media substrate.

While the disclosure has been described with reference to certain examples, those skilled in the art will appreciate that various modifications, changes, omissions, and substitutions can be made without departing from the spirit of the disclosure. It is intended, therefore, that the disclosure be limited only by the scope of the following claims.

What is claimed is:

1. A coating device, comprising:
a pre-moisturizer and pre-heater unit to apply heat and moisture to a media substrate;
a coating composition applicator to apply a wet coating composition to the media substrate after it has been heated and moisturized by the pre-moisturizer and pre-heater unit; and
a dryer to receive the media substrate having the wet coating composition applied thereto and to remove moisture, thereby generating a coated media substrate.

2. The coating device of claim 1, further comprising an air flow director to direct moistened and heated air from the dryer back to the pre-moisturizer and pre-heater unit.

3. The coating device of claim 1, wherein the pre-moisturizer and pre-heater unit includes a controller to allow for control of application of moistened and heated air that is applied to a front surface, a back surface, or both surfaces of the media substrate.

4. The coating device of claim 1, further comprising an air to air heat exchanger in fluid communication with the pre-moisturizer and pre-heater unit.

5. The coating device of claim 4, wherein air is circulated in series from the air to air heat exchanger to the dryer, from the dryer to the pre-moisturizer and pre-heater unit, and from the pre-moisturizer and pre-heater unit to the air to air heat exchanger.

6. The coating device of claim 1, wherein the coating composition applicator is adapted to independently apply the coating composition to one or both sides of the media substrate at a dry coat weight from about 0.2 gsm to about 10 gsm per side.

7. The coating device of claim 1, wherein the pre-moisturizer and pre-heating unit is adapted to provide a relative humidity ranging from about 50% to about 100%.

8. The coating device of claim 1, wherein the pre-moisturizer and pre-heating unit is adapted to provide a temperature ranging from about 40° C. to about 200° C.

9. The coating device of claim 1, further comprising a printer to receive the dry coated media substrate from the dryer and print an inkjet ink thereon, wherein the printer includes:
a print dryer to apply heat and remove moisture from the inkjet ink, and
an airflow director to direct the heat and moisture back to the pre-moisturizer and pre-heating unit.

10. The coating device of claim 1, further comprising an overprint varnisher to receive the dry coated media substrate from the dryer, wherein the overprint varnisher includes:
a varnish dryer to apply heat and remove moisture from the varnish, and
an airflow director to direct the heat and moisture back to the pre-moisturizer and pre-heating unit.

11. The coating device of claim 1, further comprising a conveyer system to automatically transfer the media substrate from the pre-moisturizer and pre-heater device to the coating composition applicator to the heater in series.

12. The coating device of claim 1, wherein the media substrate is roll-to-roll media that is adapted to be passed through the device intact prior to cutting.

13. A method of preparing a coated media substrate, comprising:
feeding a media substrate into a coating device, wherein the coating device comprises a pre-moisturizer and pre-heater unit, a coating composition applicator, and a dryer;
applying moisture and heat to the media substrate within the pre-moisturizer and pre-heater unit at a relative humidity from about 50% to about 100% and a temperature from about 40° C. and 200° C. to generate a pre-moistened and pre-heated media substrate;
applying a coating composition to the pre-heated and pre-moistened media substrate with the coating composition applicator to generate a coated wet media substrate; and
drying the coated media substrate to generate the coated media substrate.

14. The method of claim 13, further comprising directing moistened and heated air from the dryer back to the pre-moisturizer and pre-heater unit.

15. The method of claim 14, further comprising directing moistened and heated air from a printer, an overcoat varnisher, or both back to the pre-moisturizer and pre-heater unit.
